(19) United States
(12) Patent Application Publication
(10) Pub. No.: US 2025/0341851 A1
(43) Pub. Date: Nov. 6, 2025

(54) AMPLIFYING CIRCUIT AND VOLTAGE GENERATING CIRCUIT

(71) Applicant: Realtek Semiconductor Corporation, Hsinchu (TW)

(72) Inventor: Wei-Cian HONG, Hsinchu (TW)

(21) Appl. No.: 19/182,572

(22) Filed: Apr. 17, 2025

(30) Foreign Application Priority Data
May 1, 2024 (TW) 113116274

(51) Int. Cl. G05F 3/26; H03F 3/02

(52) U.S. Cl. CPC G05F 3/26; H03F 3/02

(57) ABSTRACT

An amplifying circuit includes a floating inverter amplifier and a voltage generating circuit. A threshold voltage of transistors in the floating inverter amplifier varies corresponding to an environmental condition. The voltage generating circuit is coupled with the floating inverter amplifier. The voltage generating circuit is configured to provide an operating voltage to the floating inverter amplifier. The operating voltage provided by the voltage generating circuit is linearly correlated to the threshold voltage, and the voltage generating circuit modulates a variation of the operating voltage to keep track with a variation of the threshold voltage.

### RELATED APPLICATIONS

This application claims the priority benefit of Taiwan Application Serial Number 113116274, filed May 1, 2024, which is herein incorporated by reference.

### BACKGROUND

### Technical Field

The present disclosure relates to an amplifying circuit, in particular to an amplifying circuit and a voltage generating circuit capable of reducing an impact of environmental conditions on a floating inverter amplifier.

### Description of Related Art

A floating inverter amplifier operates in two stages. At the first stage, the floating inverter amplifier charges a reservoir capacitor thereof while resetting its differential load capacitor. At the second stage, the floating inverter amplifier enables the reservoir capacitor to drive pairs of inverters, such that the inverters charge the differential load capacitor according to differential input, to realize an amplifying effect on the differential load capacitor. However, a magnitude of the current generated by the inverters at the second stage is associated with the environmental conditions (e.g., operating voltage, process variation or operating temperature) of the inverters, so a gain of the floating inverter amplifier is also susceptible to the environmental conditions.

### SUMMARY

The present disclosure provides an amplifying circuit, including a floating inverter amplifier and a voltage generating circuit. A threshold voltage of transistors in the floating inverter amplifier varies corresponding to an environmental condition. The voltage generating circuit is coupled with the floating inverter amplifier. The voltage generating circuit is configured to provide an operating voltage to the floating inverter amplifier. The operating voltage provided by the voltage generating circuit is linearly correlated to the threshold voltage, and the voltage generating circuit modulates a variation of the operating voltage to keep track with a variation of the threshold voltage.

The present disclosure provides a voltage generating circuit, including a first current generating circuit and a current-to-voltage converter circuit. The first current generating circuit includes a first multistage current mirror and a first voltage-to-current converter circuit. The first multistage current mirror includes a first output end, and is configured to generate a first output current. In response to that the first output current flows through the first output end, the first output end is configured to generate a first output voltage. The first voltage-to-current converter circuit is coupled with the first output end to receive the first output voltage, and configured to convert the first output voltage into a first operating current. The current-to-voltage converter circuit is coupled with the first voltage-to-current converter circuit to receive the first operating current, and configured to generate an operating voltage according to the first operating current. The first operating current and the operating voltage are positively correlated to a threshold voltage of any transistor of the first multistage current mirror that the first output current flows through.

One of the advantages of the above-mentioned amplifying circuit and voltage generating circuit lies in the ability of reducing an impact of environmental conditions.

### BRIEF DESCRIPTION OF THE DRAWINGS

FIG. 1 is a schematic diagram of an amplifying circuit according to an embodiment of the present disclosure.

FIG. 2 is a schematic diagram of an amplifying circuit according to an embodiment of the present disclosure.

FIG. 3 is a block diagram illustrating the functions of an amplifying circuit according to an embodiment of the present disclosure.

FIG. 4 is a block diagram illustrating the functions of an amplifying circuit according to an embodiment of the present disclosure.

### DETAILED DESCRIPTION

The embodiments of the present disclosure are described below in tandem with relevant drawings. In the drawings, identical symbols represent identical or similar components or methods/procedures.

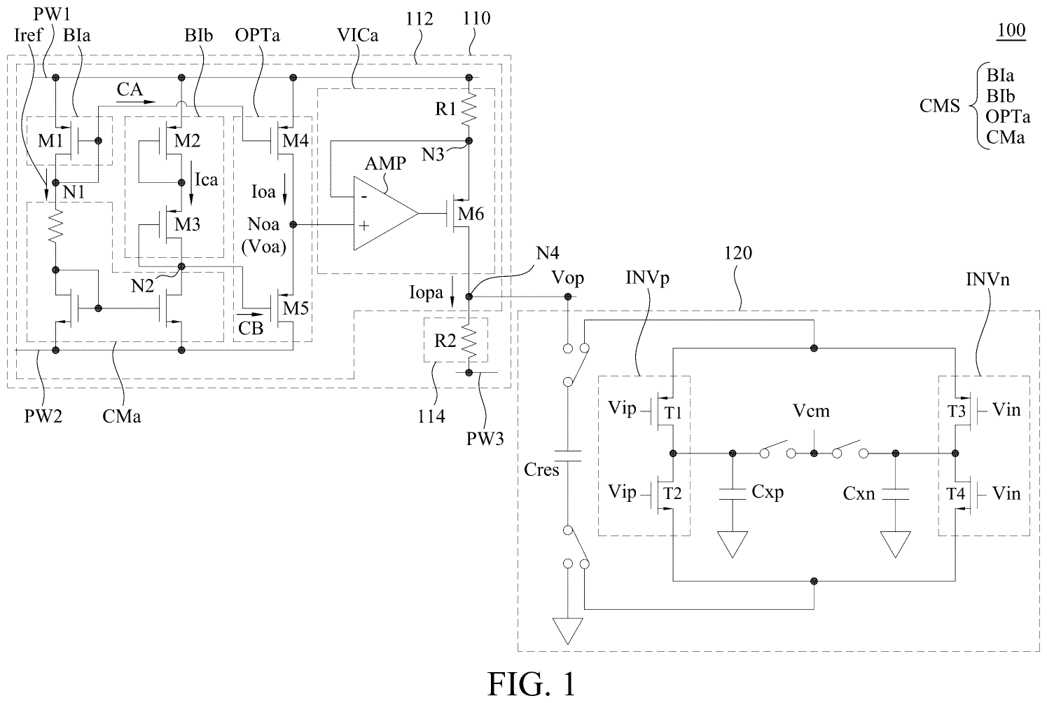

FIG. 1 is a schematic diagram of an amplifying circuit 100 according to an embodiment of the present disclosure. The amplifying circuit 100 includes a voltage generating circuit 110 and a floating inverter amplifier 120. The floating inverter amplifier 120 includes a plurality of transistors (e.g., transistors T1, T2, T3 and T4 shown in FIG. 1). Each of the transistors T1-T4 has a threshold voltage. When a voltage difference applied between the gate and source of the transistor T1-T4 is greater than the threshold voltage, the transistor T1-T4 is turned on. In practical use, as an environmental condition (e.g., process variation, operating voltage, or operating temperature) changes, the threshold voltage of the transistors T1-T4 in the floating inverter amplifier 120 varies with the environmental condition, leading to a variation of the amplifier gain of the floating inverter amplifier 120 along with the environmental condition.

In an embodiment, the voltage generating circuit 110 is configured to provide an operating voltage Vop to the floating inverter amplifier 120. It should be noted that, in some embodiments of the present disclosure, the operating voltage Vop provided by the voltage generating circuit 110 is linearly correlated to the threshold voltage of the transistors T1-T4 in the floating inverter amplifier 120, and the voltage generating circuit 110 is configured to modulate a variation of the operating voltage Vop generated thereby to keep track with a variation of the threshold voltage. Thus, an impact of the environmental condition (e.g., process variation, operating voltage, or operating temperature) on the amplifier gain of the floating inverter amplifier 120 is reduced, which then enables the floating inverter amplifier 120 to obtain a stable amplifier gain (that does not change with the process variation or operating temperature).

The voltage generating circuit 110 is coupled with the floating inverter amplifier 120, and configured to provide the operating voltage Vop to the floating inverter amplifier 120. The floating inverter amplifier 120 includes a reservoir capacitor Cres, a load capacitor Cxp, a load capacitor Cxn, an inverter INVp and an inverter INVn. The floating inverter amplifier 120 couples the reservoir capacitor Cres to the voltage generating circuit 110 at the first stage, such that the reservoir capacitor Cres is charged using the operating voltage Vop, and the load capacitors Cxp and Cxn are reset using a common mode voltage Vcm. Then, at the second stage, the floating inverter amplifier 120 couples the reservoir capacitor Cres to the inverters INVp and INVn, such that the reservoir capacitor Cres drives the inverters INVp and INVn. In addition, the floating inverter amplifier 120 couples the load capacitors Cxp and Cxn to the inverters INVp and INVn at the second stage, such that the inverters INVp and INVn charge the load capacitors Cxp and Cxn according to a differential input signal. Therefore, the floating inverter amplifier 120 can realize amplification of the input signals Vip and Vin through the load capacitors Cxp and Cxn.

The voltage generating circuit 110 includes a current generating circuit 112 and a current-to-voltage converter circuit 114. The current generating circuit 112 includes a multistage current mirror CMS and a voltage-to-current converter circuit VICa. The multistage current mirror CMS includes an output end Noa, and is configured to generate an output current Ioa. When the output current Ioa flows through the output end Noa, the output end Noa generates an output voltage Voa. The voltage-to-current converter circuit VICa is coupled with the output end Noa, to receive the output voltage Voa from the output end Noa. The voltage-to-current converter circuit VICa is configured to convert the output voltage Voa into an operating current Iopa.

The current-to-voltage converter circuit 114 is coupled with the voltage-to-current converter circuit VICa, to receive the operating current Iopa from the voltage-to-current converter circuit VICa. The current-to-voltage converter circuit 114 is configured to generate the operating voltage Vop according to the operating current Iopa. It is worth mentioning that, the operating current Iopa and the operating voltage Vop are positively correlated to the threshold voltage of any transistor (e.g., transistor M4 or M5 in FIG. 1) of the multistage current mirror CMS that the output current Ioa flows through, to offset an impact of the environmental conditions (e.g., process variation or operating temperature) of the transistors T1-T4 in the inverters INVp and INVn on the gain of the floating inverter amplifier 120.

Specifically, the multistage current mirror CMS includes a current mirror CMa, a bias circuit BIa, a bias circuit BIb and an output stage OPTa. The current mirror CMa is coupled with a power end PW2, and a first end (e.g., node N1 in FIG. 1) of the current mirror CMa is configured to receive a reference current Iref from the bias circuit BIa. Thus, a second end (e.g., node N2 in FIG. 1) of the current mirror CMa generates a mirror current Ica of the same magnitude as the reference current Iref.

The bias circuit BIa is coupled between the power end PW1 and the node N1, namely, the bias circuit BIa is coupled in series with the first end of the current mirror CMa. The bias circuit BIa is configured to generate a control signal CA according to the reference current Iref. In some embodiments, the bias circuit BIa includes a transistor M1. A first end (e.g., source) of the transistor M1 is coupled with the power end PW1, and a second end (e.g., drain) and a control end (e.g., gate) of the transistor M1 are coupled with the node N1. In other words, the transistor M1 is a diode-connected transistor, and is coupled in series between the power end PW1 and the first end of the current mirror CMa, to receive the reference current Iref. When the reference current Iref flows through the transistor M1, the second end and the control end of the transistor M1 generate the control signal CA. In some embodiments, the transistor M1 is a P-type transistor. In this embodiment, the power end PW1 may be coupled to a system high voltage, e.g., V_{DD}.

The bias circuit BIb is coupled between the power end PW1 and the node N2, namely, the bias circuit BIb is coupled in series with the second end of the current mirror CMa, to receive the mirror current Ica. The bias circuit BIb is configured to generate a control signal CB according to the mirror current Ica. In some embodiments, the bias circuit BIb includes a transistor M2 and a transistor M3. A first end (e.g., source) of the transistor M2 is coupled with the power end PW1; and a second end (e.g., drain) and a control end (e.g., gate) of the transistor M2 are coupled with a first end (e.g., source) of the transistor M3. A second end (e.g., drain) and a control end (e.g., gate) of the transistor M3 are coupled with the node N2.

In other words, the transistors M2 and M3 are diode-connected transistors, and are sequentially coupled in series between the power end PW1 and the second end of the current mirror CMa, to receive the mirror current Ica. When the mirror current Ica flows through the transistors M2 and M3, the second end (namely, node N2) of the current mirror CMa is configured to generate the control signal CB. In some embodiments, the transistors M2 and M3 are P-type transistors.

The output stage OPTa includes the output end Noa. The output stage OPTa is configured to receive the control signals CA and CB, to generate the output current Ioa under the control of the control signals CA and CB. As mentioned above, When the output current Ioa flows through the output end Noa, the output end Noa generates the output voltage Voa. Specifically, the output stage OPTa further includes a transistor M4 and a transistor M5. A first end (e.g., source) of the transistor M4 is coupled with the power end PW1; a second end (e.g., drain) of the transistor M4 is coupled with the output end Noa; and a control end (e.g., gate) of the transistor M4 is coupled with the bias circuit BIa through the node N1, to receive the control signal CA from the bias circuit BIa. A first end (e.g., source) of the transistor M5 is coupled with the output end Noa; a second end (e.g., drain) of the transistor M5 is coupled with the power end PW2; and a control end (e.g., gate) of the transistor M5 is coupled with the bias circuit BIb through the node N2, to receive the control signal CB from the bias circuit BIb. In some embodiments, the transistors M4 and M5 are P-type transistors. In this embodiment, the power end PW2 may be configured to provide a system ground end or a system low voltage, e.g., Vss.

The voltage-to-current converter circuit VICa includes a resistor R1, an amplifier AMP and a transistor M6. The resistor R1 is coupled between the power end PW1 and the node N3. A first end (e.g., non-inverting input end) of the amplifier AMP is coupled with the output end Noa to receive the output voltage Voa. A second end (e.g., inverting input end) of the amplifier AMP is coupled with the resistor R1 through the node N3. The transistor M6 is configured to generate the operating current Iopa. A first end (e.g., source) of the transistor M6 is coupled with the resistor R1 through the node N3. A second end (e.g., drain) of the transistor M6 is coupled with the current-to-voltage converter circuit 114 through the node N4. A control end (e.g., gate) of the transistor M6 is coupled with the output end of the amplifier AMP.

In other words, the resistor R1, the second end (or node N3) of the amplifier AMP and the transistor M6 are sequentially coupled in series between the power end PW1 and the current-to-voltage converter circuit 114 (or node N4). The operating current Iopa is transferred to the node N4 sequentially through the resistor R1, the node N3 and the transistor M6. In some embodiments, the transistor M6 is a P-type transistor.

The current-to-voltage converter circuit 114 includes a resistor R2. A first end of the resistor R2 is coupled with the voltage-to-current converter circuit VICa through the node N4, to receive the operating current Iopa from the voltage-to-current converter circuit VICa. A second end of the resistor R2 is coupled with the power end PW3. In the embodiment illustrated by FIG. 1, the voltage of the power end PW1 is higher than the voltage of the power end PW2, and higher than the voltage of the power end PW3, where the power ends PW2 and PW3 may have the same voltage, or not. When the operating current Iopa sequentially flows through the first end and the second end of the resistor R2, the first end (or node N4) of the resistor R2 is configured to generate the operating voltage Vop.

In some embodiments, the transistors M1, M4 and M5 have the same width-length ratio. The transistors M2 and M3 have the same width-length ratio. In some embodiments, the width-length ratio of the transistors M2 and M3 is four times that of the transistors M1, M4 and M5. Preferably, the resistors R1 and R2 have the same resistance. Since the reference current Iref, the mirror current Ica and the output current Ioa have the same magnitude, the relationship between the source-grain voltage, the operating current Iopa and the operating voltage Vop of the transistors in the voltage generating circuit 110 may be given by the following Equations 1-5.

$${V}_{SG , M 2} = {V}_{SG , M 3} \qquad Equation 1$$

$${V}_{SG , M 1} = 2 {V}_{SG , M 3} - \vert Vtp \vert = {V}_{SG , M 4} = {V}_{SG , M 5} \qquad Equation 2$$

$$Vout = Vpw 1 - \vert Vtp \vert \qquad Equation 3$$

$$Iout = \vert Vtp \vert / R 1 \qquad Equation 4$$

$$Vop = Vpw 3 + \vert Vtp \vert \qquad Equation 5$$

In aforesaid equations, symbols V_{SG,M1}, V_{SG,M2}, V_{SG,M3}, V_{SG,M4} and V_{SG,M5} represent the source-drain voltages of the transistors M1-M5 respectively; the symbol Vpw3 represents the voltage of the power end PW3; and the symbol |Vtp| represents the threshold voltage of a P-type transistor in FIG. 1. It can be seen from the equations 4 and 5 that, the operating voltage Vop is linearly correlated (positively correlated, in this embodiment) to the threshold voltage |Vtp|. Therefore, when the threshold voltages of the P-type transistors (e.g., transistors T1 and T3 in FIG. 1) of the inverters INVp and INVn increase or decrease due to a variation of an environmental condition (e.g., process variation or operating temperature), since the operating voltage Vop rises or falls along, the source-drain voltages of the P-type transistors (e.g., transistors T1 and T3 in FIG. 1) of the inverters INVp and INVn also rise or fall along, thereby reducing an impact induced by the environmental condition upon the current generated by the inverters INVp and INVn. Thus, the voltage generating circuit 110 modulates a variation of the operating voltage Vop generated thereby to keep track with a variation of the threshold voltage Vtp caused by the environmental condition.

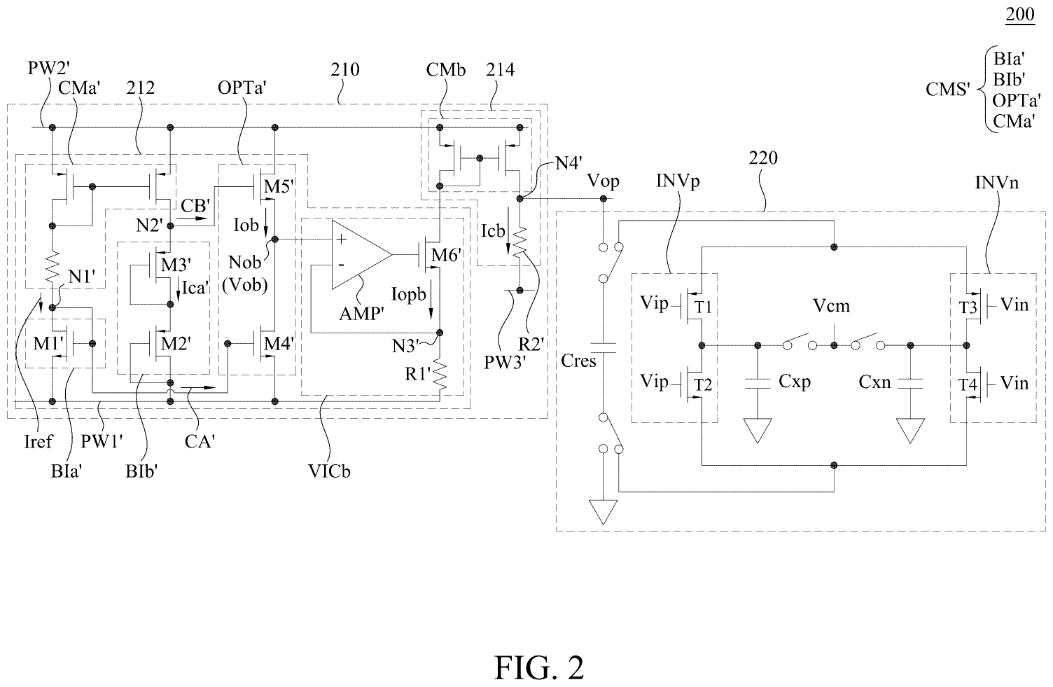

FIG. 2 is a schematic diagram of an amplifying circuit 200 according to an embodiment of the present disclosure. The amplifying circuit 200 includes a voltage generating circuit 210 and a floating inverter amplifier 220. The floating inverter amplifier 220 of FIG. 2 is similar to the floating inverter amplifier 120 of FIG. 1 in structure and operation, which are not elaborated here for the sake of conciseness. It is worth mentioning that, in the embodiment illustrated by FIG. 2, the voltage of the power end PW2′ is higher than the voltage of the power ends PW1′ and PW3′.

The voltage generating circuit 210 is configured to generate an operating voltage Vop to drive the floating inverter amplifier 220. The voltage generating circuit 210 includes a current generating circuit 212 and a current-to-voltage converter circuit 214. The current generating circuit 212 includes a multistage current mirror CMS' and a voltage-to-current converter circuit VICb. The multistage current mirror CMS' includes an output end Nob, and is configured to generate an output current Iob. When the output current Iob flows through the output end Nob, the output end Nob generates an output voltage Vob. The voltage-to-current converter circuit VICb is coupled with the output end Nob, to receive the output voltage Vob from the output end Nob. The voltage-to-current converter circuit VICb is configured to convert the output voltage Vob into an operating current Iopb.

The current-to-voltage converter circuit 214 is coupled with the voltage-to-current converter circuit VICb, to receive the operating current Iopb from the voltage-to-current converter circuit VICb. The current-to-voltage converter circuit 214 is configured to generate a mirror current Icb according to the operating current Iopb, and then to generate the operating voltage Vop according to the mirror current Icb. It is worth mentioning that, the operating current Iopb, the mirror current Icb and the operating voltage Vop are linearly correlated (positively correlated, in this embodiment) to the threshold voltage of any transistor (e.g., transistor M4′ or M5′ in FIG. 2) of the multistage current mirror CMS' that the output current Iob flows through, to offset an impact of the environmental conditions of the inverters INVp and INVn on the gain of the floating inverter amplifier 220.

The current generating circuit 212 of FIG. 2 is similar to the current generating circuit 112 of FIG. 1 in structure and operation. For example, the schematic diagram of the current generating circuit 212 of FIG. 2 is approximately a mirror of the schematic diagram of the current generating circuit 112 of FIG. 1. Thus, for the sake of conciseness, only the difference between the two is described below. The multistage current mirror CMS' includes a current mirror CMa′, a bias circuit BIa′, a bias circuit BIb′ and an output stage OPTa′. The current mirror CMa′ is coupled with the power end PW2′. Since the voltage of the power end PW2′ is higher than the voltage of the power end PW1′, a first end (e.g., node N1′ in FIG. 2) of the current mirror CMa′ is configured to transfer a reference current Iref′ to the bias circuit BIa′. A second end (e.g., node N2′ in FIG. 2) of the current mirror CMa′ outputs a mirror current Ica′ of the same magnitude as the reference current Iref′.

The bias circuit BIa′ includes a transistor M1′. In some embodiments, the transistor M1′ of the bias circuit BIa′ is an N-type transistor, and includes a first end (e.g., source), a second end (e.g., drain) and a control end (e.g., gate). When the reference current Iref′ sequentially flows through the second end and the first end of the transistor M1′, the second end and the control end of the transistor M1′ generate a control signal CA′.

One end of the bias circuit BIb′ is coupled with the second end of the current mirror CMa′ through the node N2′, and the other end of the bias circuit BIb′ is coupled with the power end PW1′. The bias circuit BIb′ includes a transistor M2′ and a transistor M3′. A first end (e.g., source) of the transistor M3′ is coupled with the node N2′; and a second end (e.g., drain) and a control end (e.g., gate) of the transistor M3′ are coupled with a first end (e.g., source) of the transistor M2′. A second end (e.g., drain) and a control end (e.g., gate) of the transistor M2′ are coupled with the power end PW1′.

In other words, the transistors M2′ and M3′ are diode-connected transistors, and are sequentially coupled in series between the power end PW1′ and the second end of the current mirror CMa′, to receive the mirror current Ica′. When the mirror current Ica′ flows through the transistors M2′ and M3′, the second end (namely, node N2′) of the current mirror CMa′ is configured to generate a control signal CB′. In some embodiments, the transistors M2′ and M3′ are P-type transistors.

The output stage OPTa′ is configured to receive the control signals CA′ and CB′, to generate the output current Iob. The output stage OPTa′ includes an output end Nob, a transistor M4′ and a transistor M5′. The control ends (e.g., gate) of the transistors M4′ and M5′ are configured to receive the control signals CA′ and CB′ respectively. The transistor M4′, the output end Nob and the transistor M5′ are sequentially coupled in series between the power end PW1′ and the power end PW2′. When the output current Iob flows through the output end Nob, the output end Nob generates an output voltage Vob. In addition, in the embodiment illustrated by FIG. 2, the control end of the transistor M4′ is coupled with the bias circuit BIa′ (e.g., the second end and the control end of the transistor M1′), to receive the control signal CA′. In some embodiments, the transistors M4′ and M5′ are N-type transistors.

The voltage-to-current converter circuit VICb includes a resistor R1′, an amplifier AMP′ and a transistor M6′. The voltage-to-current converter circuit VICb is configured to receive the output voltage Vob from the output end Nob, and to convert the output voltage Vob into the operating current Iopb. In some embodiments, the transistor M6′ is an N-type transistor, and includes a first end (e.g., drain), a second end (e.g., source) and a control end (e.g., gate). The first end of the transistor M6′ is coupled with the current-to-voltage converter circuit 214. A first end (e.g., non-inverting input end) of the amplifier AMP′ is coupled with the output end Nob to receive the output voltage Vob. A second end (e.g., inverting input end) of the amplifier AMP′ is coupled with the resistor R1′ and the second end of the transistor M6′ through the node N3′. An output end of the amplifier AMP′ is coupled with the control end of the transistor M6′.

In other words, the resistor R1′, the second end (or node N3′) of the amplifier AMP′ and the transistor M6′ are sequentially coupled in series between the power end PW1′ and the current-to-voltage converter circuit 214. The operating current Iopb sequentially flows through the transistor M6′, the node N3′, the resistor R1′ and the power end PW1′.

The current-to-voltage converter circuit 214 includes a current mirror CMb and a resistor R2′. A first end of the current mirror CMb is coupled with the voltage-to-current converter circuit VICb (e.g., the first end, drain, of the transistor M6′) to output the operating current Iopb. Thus, a second end (e.g., node N4′ in FIG. 2) of the current mirror CMb generates a mirror current Icb of the same magnitude as the operating current Iopb. A first end of the resistor R2′ is coupled with the second end of the current mirror CMb through the node N4′, to receive the mirror current Icb. A second end of the resistor R2′ is coupled with the power end PW3′. When the mirror current Icb sequentially flows through the first end and the second end of the resistor R2′, the first end (or node N4′) of the resistor R2′ is configured to generate the operating voltage Vop. It is worth mentioning that, the resistors R1′ and R2′ have the same resistance.

Therefore, in the embodiment illustrated by FIG. 2, the operating voltage Vop has a magnitude of Vpw3′+Vtn. The symbol Vpw3′ represents the voltage of the power end PW3′. The symbol Vtn represents the threshold voltage of any N-type transistor in FIG. 2. In other words, the operating voltage Vop is linearly correlated (positively correlated, in this embodiment) to the threshold voltage Vtn. Therefore, when the threshold voltages of the N-type transistors (e.g., transistors T2 and T4 in FIG. 2) of the inverters INVp and INVn go up or down due to a variation of process variation or operating temperature, since the operating voltage Vop rises or falls along, the source-drain voltages of the N-type transistors (e.g., transistors T2 and T4 in FIG. 2) of the inverters INVp and INVn also rise or fall along, thereby reducing an impact of the environmental condition on the current generated by the inverters INVp and INVn. So, the amplifying circuit 200 of FIG. 2 can reduce an impact of a variation of the threshold voltages of the N-type transistors on the floating inverter amplifier 220.

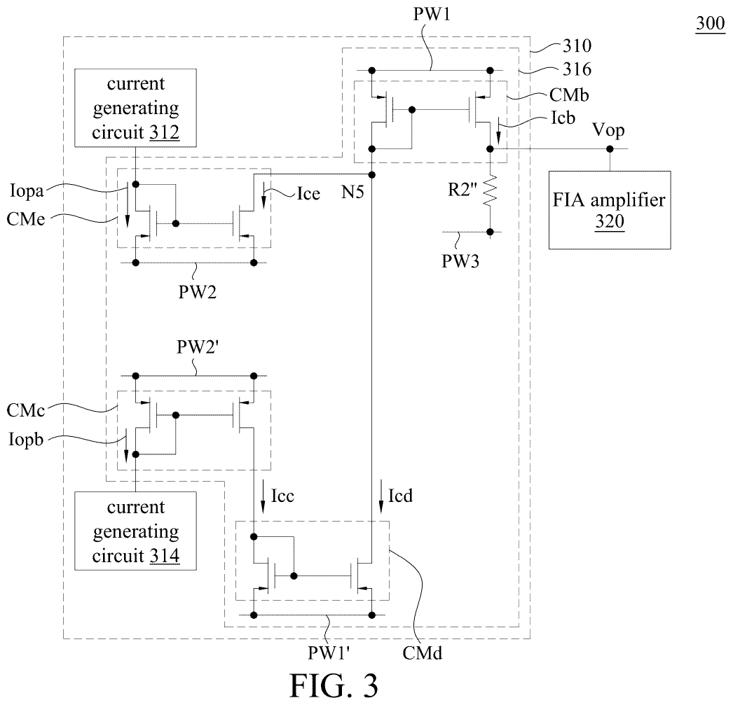

FIG. 3 is a block diagram illustrating the functions of an amplifying circuit 300 according to an embodiment of the present disclosure. The amplifying circuit 300 includes a voltage generating circuit 310 and a floating inverter amplifier 320. The floating inverter amplifier 320 of FIG. 3 is similar to the floating inverter amplifier 120 of FIG. 1 in structure and operation, which are not elaborated here for the sake of conciseness. The voltage generating circuit 310 includes a current generating circuit 312, a current generating circuit 314 and a current-to-voltage converter circuit 316. The current generating circuit 312 of FIG. 3 can be implemented by the current generating circuit 112 of FIG. 1. The current generating circuit 314 of FIG. 3 can be implemented by the current generating circuit 212 of FIG. 2.

In other words, the current generating circuit 312 includes a multistage current mirror CMS and a voltage-to-current converter circuit VICa (please refer to the current generating circuit 112 of FIG. 1 at the same time). As shown in FIG. 1, the multistage current mirror CMS includes an output end Noa, and is configured to generate an output current Ioa. The output current Ioa flows through the output end Noa to generate an output voltage Voa. The voltage-to-current converter circuit VICa is coupled with the output end Noa to receive the output voltage Voa, and to convert the output voltage Voa into an operating current Iopa. In addition, the current generating circuit 314 includes a multistage current mirror CMS' and a voltage-to-current converter circuit VICb (please refer to the current generating circuit 212 of FIG. 2 at the same time). As shown in FIG. 2, the multistage current mirror CMS' includes an output end Nob, and is configured to generate an output current Iob. The output current Iob flows through the output end Nob to generate an output voltage Vob. The voltage-to-current converter circuit VICb is coupled with the output end Nob to receive the output voltage Vob, and to convert the output voltage Vob into an operating current Iopb.

The current-to-voltage converter circuit 316 is configured to generate an operating voltage Vop according to the sum of the operating current Iopa and the operating current Iopb. The current-to-voltage converter circuit 316 includes a current mirror CMb, a current mirror CMc, a current mirror CMd, a current mirror CMe and a resistor R2″. The current mirror CMb includes a first end (e.g., node N5 of FIG. 3) and a second end, and is coupled with the power end PW1. A second end of the current mirror CMb is configured to output a mirror current Icb. The current mirror CMc includes a first end and a second end, and is coupled with the power end PW2′. The first end of the current mirror CMc is coupled with the current generating circuit 314 (e.g., the current generating circuit 314 can be implemented by the current generating circuit 212 of FIG. 2, and the first end of the current mirror CMc of FIG. 3 is coupled with the first end (drain) of the transistor M6′ of the voltage-to-current converter circuit VICb of FIG. 2), to output the operating current Iopb to the current generating circuit 314. The generation process of the operating current Iopb is similar to the content mentioned above in tandem with FIG. 2, which is not elaborated here for the sake of conciseness. The second end of the current mirror CMc is configured to generate a mirror current Icc of the same magnitude as the operating current Iopb.

The current mirror CMd includes a first end and a second end, and is coupled with the power end PW1′. The first end of the current mirror CMd is coupled with the second end of the current mirror CMc to receive the mirror current Icc. The second end of the current mirror CMb is coupled with the first end (e.g., node N5) of the current mirror CMb, and configured to generate a mirror current Icd of the same magnitude as the mirror current Icc. The current mirror CMe includes a first end and a second end, and is coupled with the power end PW2. The first end of the current mirror CMe is coupled with the current generating circuit 312 (e.g., the current generating circuit 312 of FIG. 3 can be implemented by the current generating circuit 112 of FIG. 1, and the first end of the current mirror CMe of FIG. 3 can be coupled with the second end (drain) of the transistor M6 of the voltage-to-current converter circuit VICa of FIG. 1), to receive the operating current Iopa from the current generating circuit 312. The generation process of the operating current Iopa is similar to the content mentioned above in tandem with FIG. 1, which is not elaborated here for the sake of conciseness. The second end of the current mirror CMe is coupled with the first end (e.g., node N5) of the current mirror CMb, and configured to generate a mirror current Ice of the same magnitude as the operating current Iopa.

It can be seen from the above that, the magnitude of the current of the node N5 is equal to the sum of the mirror current Icd and Ice, namely, equal to the sum of the operating current Iopa and Iopb. Thus, the magnitude of the mirror current Icb at the second end of the current mirror CMb is equal to the sum of the operating current Iopa and Iopb (namely, Icb=Iopa+Iopb).

The resistor R2″ includes a first end and a second end. The first end of the resistor R2″ is coupled with the second end of the current mirror CMb to receive the mirror current Icb. The second end of the resistor R2″ is coupled with the power end PW3. When the mirror current Icb, from the current mirror CMb, sequentially flows through the first end and the second end of the resistor R2″, the first end of the resistor R2″ generates the operating voltage Vop.

In this embodiment, the resistor R2″ has the same resistance as the resistor R1 of FIG. 1 and the resistor R1′ of FIG. 2. Therefore, in the embodiment illustrated by FIG. 3, the operating voltage Vop has a magnitude of Vpw3′+Vtn+|Vtp|. The symbol Vpw3 represents the voltage of the power end PW3. The symbol Vtn represents the threshold voltage of any N-type transistor in FIGS. 1-3. The symbol |Vtp| represents the threshold voltage of any P-type transistor in FIGS. 1-3. In a word, the amplifying circuit 300 of FIG. 3 can simultaneously reduce an impact of a variation of the threshold voltages of the N-type transistors and P-type transistors on the floating inverter amplifier 320.

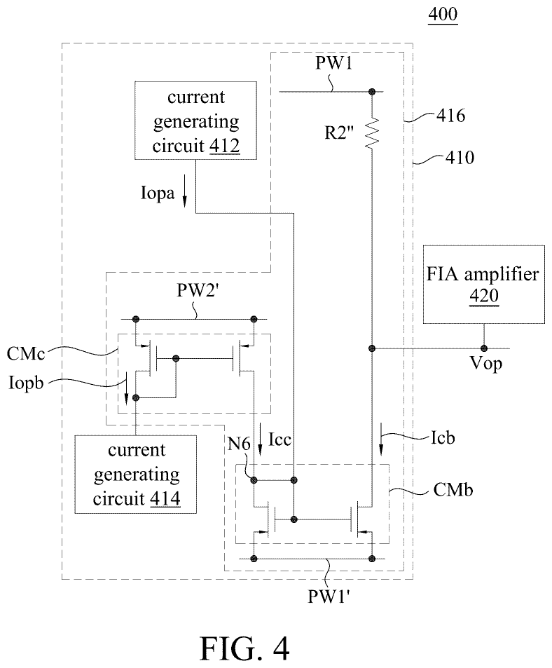

In the above-mentioned embodiments of FIGS. 1-3, the operating voltage Vop is provided, as a high voltage, to the upper end of the reservoir capacitor Cres of the floating inverter amplifier, coupled with the P-type transistor. The lower end of the reservoir capacitor Cres, coupled with the N-type transistor, is configured to receive a low voltage lower than the operating voltage Vop. In some embodiments, as shown in FIG. 4, the operating voltage Vop is provided, as a low voltage, to the lower end of the reservoir capacitor Cres, coupled with the N-type transistor, and the upper end of the reservoir capacitor Cres, coupled with the P-type transistor, is configured to receive a high voltage higher than the operating voltage Vop.

FIG. 4 is a block diagram illustrating the functions of an amplifying circuit 400 according to an embodiment of the present disclosure. The amplifying circuit 400 includes a voltage generating circuit 410 and a floating inverter amplifier 420. The floating inverter amplifier 420 of FIG. 4 is similar to the floating inverter amplifier 120 of FIG. 1 in structure and operation, which are not elaborated here for the sake of conciseness. The voltage generating circuit 410 includes a current generating circuit 412, a current generating circuit 414 and a current-to-voltage converter circuit 416. The current generating circuit 412 of FIG. 4 can be implemented by the current generating circuit 112 of FIG. 1, namely, the current generating circuit 412 is configured to generate an operating current Iopa. The current generating circuit 414 of FIG. 4 can be implemented by the current generating circuit 212 of FIG. 2, namely, the current generating circuit 414 is configured to generate an operating current Iopb.

The current-to-voltage converter circuit 416 includes a current mirror CMb, a current mirror CMc and a resistor R2″. The current mirror CMb includes a first end (e.g., node N6 of FIG. 4) and a second end, and is coupled with the power end PW1′. The second end of the current mirror CMb is configured to generate a mirror current Icb. The first end of the current mirror CMc is coupled with the current generating circuit 414 (e.g., the current generating circuit 414 of FIG. 4 can be implemented by the current generating circuit 212 of FIG. 2, and the first end of the current mirror CMc of FIG. 4 can be coupled with the first end (drain) of the transistor M6′ of the voltage-to-current converter circuit VICb of FIG. 2), to output the operating current Iopb to the current generating circuit 414. The generation process of the operating current Iopb is similar to the content mentioned above in tandem with FIG. 2, which is not elaborated here for the sake of conciseness. The second end of the current mirror CMc is coupled with the first end (e.g., node N6) of the current mirror CMb, and configured to generate a mirror current Icc of the same magnitude as the operating current Iopb.

The first end (e.g., node N6) of the current mirror CMb is coupled with the second end of the current mirror CMc and the current generating circuit 412, to receive the operating current Iopa and the mirror current Icc. The generation process of the operating current Iopa is similar to the content mentioned above in tandem with FIG. 1, which is not elaborated here for the sake of conciseness. In a word, the magnitude of the mirror current Icb is equal to the sum of the operating current Iopa and the mirror current Icc (namely, Icb=Iopa+Icc). The resistor R2″ includes a first end and a second end. The first end of the resistor R2″ is coupled with the power end PW1. The second end of the resistor R2″ is coupled with the second end of the current mirror CMb, to output the mirror current Icb. When the mirror current Icb sequentially flows through the first end and the second end of the resistor R2″ before being transferred to the current mirror CMb, the second end of the resistor R2″ is configured to generate the operating voltage Vop.

In this embodiment, the resistor R2″ has the same resistance as the resistor R1 of FIG. 1 and the resistor R1′ of FIG. 2. Therefore, in the embodiment illustrated by FIG. 4, the operating voltage Vop has a magnitude of Vpw1−Vtn−|Vtp|. The symbol Vpw1 represents the voltage of the power end PW1. The symbol Vtn represents the threshold voltage of any N-type transistor in FIGS. 1, 2 and 4. The symbol |Vtp| represents the threshold voltage of any P-type transistor in FIGS. 1, 2 and 4. In a word, the amplifying circuit 400 of FIG. 4 can simultaneously reduce an impact of a variation of the threshold voltages of the N-type transistors and P-type transistors on the floating inverter amplifier 420.

The operating voltage Vop provided by the voltage generating circuit 410 in the amplifying circuit 400 is linearly correlated (negatively correlated, in this embodiment) to the threshold voltages of the transistors in the floating inverter amplifier 420, and the voltage generating circuit 410 is configured to modulate a variation of the operating voltage Vop generated thereby to keep track with a variation of the threshold voltages. Thus, an impact of an environmental condition (e.g., process variation, operating voltage, or operating temperature) on the amplifier gain of the floating inverter amplifier 420 is reduced, which then enables the floating inverter amplifier 420 to obtain a stable amplifier gain (that does not change with the process variation or operating temperature).

In the embodiments illustrated by FIG. 3 and FIG. 4, the voltage of the power ends PW1 and PW2′ is higher than the voltage of the power ends PW1′ and PW2, and higher than the voltage of the power end PW3. The power ends PW1 and PW2′ may have the same voltage or not. The power ends PW1′ and PW2 may have the same voltage or not.

Certain terms are utilized in the Specification and Claims to indicate particular components. However, those of common knowledge in the art shall understand that, identical components may be called different names. In the Specification and Claims, the components are not distinguished as per the difference in name, but based on the difference in function. The term “includes” mentioned in the Specification and Claims is open-ended, and thus shall be interpreted as “includes but not limited to”. In addition, “coupled with” here includes any direct and indirect connection means. Therefore, a description of a first component being coupled with a second component herein indicates that the first component may be directly connected with the second component through electrical connection or signal connection such as wireless transmission and optical transmission, or may be indirectly connected to the second component through electrical connection or signal connection via other components or connection means.

Only preferred embodiments of the present disclosure are described above, and various modification and equivalent variations may be made to the present disclosure without departing from the scope or spirit of the present disclosure. In conclusion, all modifications and equivalent variations made to the present disclosure within the scope of the following claims shall fall within the scope of the present disclosure.

What is claimed is:

1. An amplifying circuit, comprising:
a floating inverter amplifier, wherein a threshold voltage of a transistor in the floating inverter amplifier varies corresponding to an environmental condition; and
a voltage generating circuit, coupled with the floating inverter amplifier, and configured to provide an operating voltage to the floating inverter amplifier, wherein the operating voltage provided by the voltage generating circuit is linearly correlated to the threshold voltage, and the voltage generating circuit modulates a variation of the operating voltage to keep track with a variation of the threshold voltage.

2. The amplifying circuit of claim 1, wherein the voltage generating circuit comprises a first current generating circuit and a current-to-voltage converter circuit, wherein the first current generating circuit comprises:
a first multistage current mirror, comprising a first output end and configured to generate a first output current, wherein in response to that the first output current flows through the first output end, the first output end is configured to generate a first output voltage; and
a first voltage-to-current converter circuit, coupled with the first output end to receive the first output voltage, and configured to convert the first output voltage into a first operating current;
wherein the current-to-voltage converter circuit is coupled with the first voltage-to-current converter circuit to receive the first operating current, and configured to generate the operating voltage according to the first operating current,
wherein the first operating current and the operating voltage are positively correlated to another threshold voltage of any transistor of the first multistage current mirror that the first output current flows through.

3. The amplifying circuit of claim 2, wherein the first multistage current mirror comprises:
a first current mirror, wherein a first end of the first current mirror is configured to receive a reference current, such that a second end of the first current mirror generates a first mirror current;
a first bias circuit, coupled in series with the first end of the first current mirror, and configured to generate a first control signal according to the reference current;
a second bias circuit, coupled in series with the second end of the first current mirror, and configured to generate a second control signal according to the first mirror current; and
a first output stage, comprising the first output end, and wherein the first output stage is controlled by the first control signal and the second control signal and is configured to generate the first output current.

4. The amplifying circuit of claim 3, wherein the second bias circuit comprises:
a second transistor; and
a third transistor, wherein the second transistor and the third transistor are diode-connected transistors, and are sequentially coupled in series between a first power end and the second end of the first current mirror, to receive the first mirror current,
wherein in response to that the first mirror current flows through the second transistor and the third transistor, the second end of the first current mirror is configured to generate the second control signal, and a voltage of the first power end is greater than a voltage of a second power end.

5. The amplifying circuit of claim 2, wherein the first voltage-to-current converter circuit comprises:
a first resistor;
an amplifier, wherein a first end of the amplifier is coupled with the first output end to receive the first output voltage, and a second end of the amplifier is coupled with the first resistor; and
a sixth transistor, configured to generate the first operating current, wherein a control end of the sixth transistor is coupled with an output end of the amplifier,
wherein the first resistor, the second end of the amplifier and the sixth transistor are sequentially coupled in series between a first power end and the current-to-voltage converter circuit.

6. The amplifying circuit of claim 1, wherein the voltage generating circuit comprises a second current generating circuit and a current-to-voltage converter circuit, wherein the second current generating circuit comprises:
a second multistage current mirror, comprising a second output end and configured to generate a second output current, wherein in response to that the second output current flows through the second output end, the second output end is configured to generate a second output voltage; and
a second voltage-to-current converter circuit, coupled with the second output end to receive the second output voltage, and configured to convert the second output voltage into a second operating current,
wherein the current-to-voltage converter circuit is coupled with the second voltage-to-current converter circuit to receive the second operating current, and configured to generate the operating voltage according to the second operating current,
wherein the second operating current and the operating voltage are positively correlated to another threshold voltage of any transistor of the second multistage current mirror that the second output current flows through.

7. The amplifying circuit of claim 1, wherein the voltage generating circuit comprises a first current generating circuit, a second current generating circuit and a current-to-voltage converter circuit, wherein the first current generating circuit is configured to generate a first operating current, the second current generating circuit is configured to generate a second operating current, and the current-to-voltage converter circuit is configured to generate the operating voltage according to a sum of the first operating current and the second operating current.

8. The amplifying circuit of claim 7, wherein the current-to-voltage converter circuit comprises:
a second current mirror, comprising a first end and a second end, wherein the second end of the second current mirror is configured to generate a second mirror current;
a third current mirror, wherein a first end of the third current mirror is coupled with the second current generating circuit to output the second operating current, and a second end of the third current mirror is configured to generate a third mirror current;
a fourth current mirror, wherein a first end of the fourth current mirror is coupled with the second end of the third current mirror to receive the third mirror current, and a second end of the fourth current mirror is coupled with the first end of the second current mirror and configured to generate a fourth mirror current;
a fifth current mirror, wherein a first end of the fifth current mirror is coupled with the first current generating circuit to receive the first operating current, and a second end of the fifth current mirror is coupled with the first end of the second current mirror and configured to generate a fifth mirror current; and
a second resistor, wherein the first end of the second current mirror is configured to receive the fourth mirror current and the fifth mirror current, and a first end of the second resistor is coupled with the second end of the second current mirror to receive the second mirror current, wherein in response to that the second mirror current sequentially flows from the second current mirror through the first end and a second end of the second resistor, the first end of the second resistor is configured to generate the operating voltage.

9. The amplifying circuit of claim 7, wherein the current-to-voltage converter circuit comprises:
a second current mirror;
a third current mirror, wherein a first end of the third current mirror is coupled with the second current generating circuit to output the second operating current, and a second end of the third current mirror is coupled with a first end of the second current mirror and configured to generate a third mirror current, wherein the first end of the second current mirror is configured to receive the first operating current and the third mirror current, and a second end of the second current mirror is configured to generate a second mirror current; and
a second resistor, comprising a first end and a second end, wherein the second end of the second resistor is coupled with the second end of the second current mirror to output the second mirror current, and in response to that the second mirror current sequentially flows through the first end and the second end of the second resistor and transfers to the second current mirror, the second end of the second resistor is configured to generate the operating voltage.

10. A voltage generating circuit, comprising:
a first current generating circuit, comprising:
a first multistage current mirror, comprising a first output end and configured to generate a first output current, wherein in response to that the first output current flows through the first output end, the first output end is configured to generate a first output voltage; and
a first voltage-to-current converter circuit, coupled with the first output end to receive the first output voltage, and configured to convert the first output voltage into a first operating current; and
a current-to-voltage converter circuit, coupled with the first voltage-to-current converter circuit to receive the first operating current, and configured to generate an operating voltage according to the first operating current,
wherein the first operating current and the operating voltage are positively correlated to a threshold voltage of any transistor of the first multistage current mirror that the first output current flows through.

11. The voltage generating circuit of claim 10, wherein the first multistage current mirror comprises:
a first current mirror, wherein a first end of the first current mirror is configured to receive a reference current, such that a second end of the first current mirror generates a first mirror current;
a first bias circuit, coupled in series with the first end of the first current mirror, and configured to generate a first control signal according to the reference current;
a second bias circuit, coupled in series with the second end of the first current mirror, and configured to generate a second control signal according to the first mirror current; and
a first output stage, comprising the first output end, wherein the first output stage is controlled by the first control signal and the second control signal and configured to generate the first output current.

12. The voltage generating circuit of claim 11, wherein the first bias circuit comprises:
a first transistor, wherein the first transistor is a diode-connected transistor, and is coupled in series between a first power end and the first end of the first current mirror, to receive the reference current,
wherein a control end of the first transistor is configured to generate the first control signal.

13. The voltage generating circuit of claim 11, wherein the second bias circuit comprises:
a second transistor; and
a third transistor, wherein the second transistor and the third transistor are diode-connected transistors, and are sequentially coupled in series between a first power end and the second end of the first current mirror, to receive the first mirror current,
wherein, when the first mirror current flows through the second transistor and the third transistor, the second end of the first current mirror is configured to generate the second control signal, and a voltage of the first power end is greater than a voltage of a second power end.

14. The voltage generating circuit of claim 11, wherein the first output stage further comprises:
a fourth transistor; and
a fifth transistor, wherein the fourth transistor, the first output end and the fifth transistor are sequentially coupled in series between a first power end and a second power end,
wherein a control end of the fourth transistor is coupled with the first bias circuit to receive the first control signal, and a control end of the fifth transistor is coupled with the second bias circuit to receive the second control signal.

15. The voltage generating circuit of claim 10, wherein the first voltage-to-current converter circuit comprises:
a first resistor;
an amplifier, wherein a first end of the amplifier is coupled with the first output end to receive the first output voltage, and a second end of the amplifier is coupled with the first resistor; and
a sixth transistor, configured to generate the first operating current, wherein a control end of the sixth transistor is coupled with a first output end of the amplifier,
wherein the first resistor, the second end of the amplifier and the sixth transistor are sequentially coupled in series between a first power end and the current-to-voltage converter circuit.

16. The voltage generating circuit of claim 10, wherein the current-to-voltage converter circuit comprises:
a second resistor, wherein a first end of the second resistor is coupled with the first voltage-to-current converter circuit to receive the first operating current; and in response to that the first operating current sequentially flows through the first end and a second end of the second resistor, the first end of the second resistor is configured to generate the operating voltage.

17. The voltage generating circuit of claim 10, further comprising:
a second current generating circuit, comprising:
a second multistage current mirror, comprising a second output end and configured to generate a second output current, wherein the second output current flows through the second output end to generate a second output voltage; and
a second voltage-to-current converter circuit, coupled with the second output end to receive the second output voltage, and configured to convert the second output voltage into a second operating current,
wherein the current-to-voltage converter circuit is configured to generate the operating voltage according to a sum of the first operating current and the second operating current,
wherein the second operating current is positively correlated to a threshold voltage of any transistor of the second multistage current mirror that the second output current flows through.

18. The voltage generating circuit of claim 17, wherein the current-to-voltage converter circuit comprises:
a second current mirror, comprising a first end and a second end, wherein the second end of the second current mirror is configured to generate a second mirror current;
a third current mirror, wherein a first end of the third current mirror is coupled with the second current generating circuit to output the second operating current, and a second end of the third current mirror is configured to generate a third mirror current;
a fourth current mirror, wherein a first end of the fourth current mirror is coupled with the second end of the third current mirror to receive the third mirror current, and a second end of the fourth current mirror is coupled with the first end of the second current mirror and configured to generate a fourth mirror current;
a fifth current mirror, wherein a first end of the fifth current mirror is coupled with the first current generating circuit to receive the first operating current, and a second end of the fifth current mirror is coupled with the first end of the second current mirror and configured to generate a fifth mirror current; and
a second resistor, wherein the first end of the second current mirror is configured to receive the fourth mirror current and the fifth mirror current, and a first end of the second resistor is coupled with the second end of the second current mirror to receive the second mirror current, wherein in response to that the second mirror current sequentially flows from the second current mirror through the first end and a second end of the second resistor, the first end of the second resistor is configured to generate the operating voltage.

19. The voltage generating circuit of claim 17, wherein the current-to-voltage converter circuit comprises:
a second current mirror;
a third current mirror, wherein a first end of the third current mirror is coupled with the second current generating circuit to output the second operating current, and a second end of the third current mirror is coupled with a first end of the second current mirror and configured to generate a third mirror current, wherein the first end of the second current mirror is configured to receive the first operating current and the third mirror current, and a second end of the second current mirror is configured to generate a second mirror current; and
a second resistor, comprising a first end and a second end, wherein the second end of the second resistor is coupled with the second end of the second current mirror to output the second mirror current; and in response to that the second mirror current sequentially flows through the first end and the second end of the second resistor and transfers to the second current mirror, the second end of the second resistor is configured to generate the operating voltage.
